(19) United States
(12) Patent Application Publication
(10) Pub. No.: US 2025/0330154 A1
(43) Pub. Date: Oct. 23, 2025

(54) DRIVER CIRCUIT

(71) Applicant: FUJI ELECTRIC CO., LTD., Kawasaki-shi (JP)

(72) Inventor: Tetsuya KAWASHIMA, Matsumoto-city (JP)

(73) Assignee: FUJI ELECTRIC CO., LTD., Kawasaki-shi (JP)

(21) Appl. No.: 19/088,392

(22) Filed: Mar. 24, 2025

(30) Foreign Application Priority Data
Apr. 18, 2024 (JP) 2024-067606

(51) Int. Cl. H03K 3/013; H01T 15/00

(52) U.S. Cl. CPC H03K 3/013; H01T 15/00

(57) ABSTRACT

A driver circuit, including: a transistor including a ground side electrode, a control electrode, and a power supply side electrode for an inductive load to be connected thereto; a first resistor connected to the control electrode; a line connected to the first resistor; a second resistor provided between the line and a ground; a first diode, including a cathode connected to the line and an anode, the first diode being connected in parallel with the second resistor; and a second diode including a cathode connected to the line, and an anode for connecting to a capacitor, thereby receiving a voltage generated in the capacitor for driving the transistor.

### CROSS-REFERENCE TO RELATED APPLICATIONS

The present application claims priority pursuant to 35 U.S.C. § 119 from Japanese patent application number 2024-067606 filed on Apr. 18, 2024, the entire disclosure of which is hereby incorporated by reference herein.

### BACKGROUND

### Technical Field

The present disclosure relates to a driver circuit.

### Description of the Related Art

An igniter including a transistor is known for driving a load such as an ignition device in an internal combustion engine of a vehicle or the like (For example, see Japanese Patent Application Publication Nos. 2022-176842, 2016-17512, 2008-45514, and 2023-43775).

In some cases, a capacitor is connected to an output stage of a circuit that outputs a signal for controlling the transistor for driving the load. In this case, when the transistor is turned off, there is a risk that oscillation of a voltage on the ground side causes charging and discharging of the capacitor, and the transistor erroneously operates.

### SUMMARY

A driver circuit of the present disclosure which solves the above-described problem comprises a transistor including a ground side electrode, a control electrode, and a power supply side electrode for an inductive load to be connected thereto; a first resistor connected to the control electrode; a line connected to the first resistor; a second resistor provided between the line and a ground; a first diode, including: a cathode connected to the line, and an anode, the first diode being connected in parallel with the second resistor; and a second diode including: a cathode connected to the line, and an anode for connecting to a capacitor, thereby receiving a voltage generated in the capacitor for driving the transistor.

### BRIEF DESCRIPTION OF THE DRAWINGS

FIG. 1 is a block diagram illustrating a configuration of an ignition system 1A using a general driver circuit 30A.

FIG. 2 is a diagram for explaining an operation in ignition of the ignition system 1A.

FIG. 3 is a block diagram illustrating a configuration of an ignition system 1 using a driver 30 of the present embodiment.

FIG. 4 is an explanatory diagram illustrating a state of a current flowing in the driver circuit 30 in the case where an IGBT 32 is turned off.

FIG. 5 is a diagram for explaining an operation in ignition of the ignition system 1.

### DETAILED DESCRIPTION

At least the following matters are apparent from the description of the present specification and the attached drawings.

Hereinafter, identical or equivalent components, members, and the like illustrated in the drawings are denoted by the same reference numerals, and overlapping explanation is omitted as appropriate in some cases.

Moreover, in the present embodiment, “coupling” refers to a state of electrical coupling unless otherwise noted. Accordingly, “coupling” includes the case where two parts are connected to each other via not only wiring but also, for example, a resistor or a terminal.

### Embodiments

In an internal combustion engine for a vehicle that uses gasoline as a fuel, an ignition system is used to ignite an air-fuel mixture of the fuel and air charged into a combustion chamber of the internal combustion engine at a predetermined timing to combust the air-fuel mixture.

In such ignition system, an igniter is provided with a transistor configured to drive an ignition coil. For example, an insulate gate bipolar transistor (IGBT) or the like is used as the transistor.

Before giving explanation of the ignition system of the present embodiment, a general ignition system (reference example) is explained.

### Reference Example

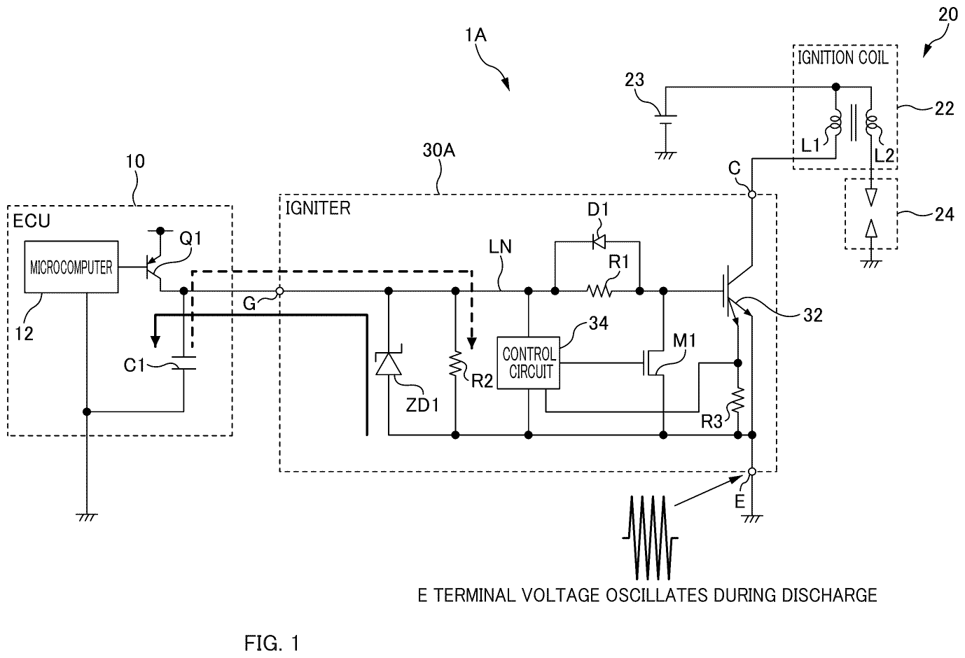

FIG. 1 is a block diagram illustrating a configuration of an ignition system 1A using a general driver circuit 30A. The driver circuit 30A corresponds to an igniter for ignition control of an internal combustion engine. Hereinafter, the driver circuit 30A is also referred to as igniter 30A.

The ignition system 1A is a system for an internal combustion engine mounted on a vehicle, and includes an electronic control unit (ECU) 10, an ignition device 20, and the igniter 30A.

### ECU 10

The ECU 10 is an apparatus that performs electronic control of the internal combustion engine, and is configured to include a microcomputer 12, a PNP transistor Q1, and a capacitor C1.

A predetermined power supply voltage (for example, 5 V) is applied to an emitter electrode of the PNP transistor Q1. Moreover, a collector electrode of the PNP transistor Q1 is connected to a gate terminal (describe later) of the igniter (igniter 30A in this case), and is grounded via the capacitor C1.

The microcomputer 12 controls on and off of the PNP transistor Q1 at an appropriate ignition timing. Specifically, the microcomputer 12 outputs a high level (hereinafter, referred to as high or high level) or low level (hereinafter, referred to as low or low level) signal to a base electrode of the PNP transistor Q1. When an output of the microcomputer 12 is high, the PNP transistor Q1 is turned off. The capacitor C1 is not charged since the PNP transistor Q1 is turned off (as described later, the capacitor C1 is discharged via the igniter 30A). In contrast, when the output of the microcomputer 12 is low, the PNP transistor Q1 is turned on. The capacitor C1 is charged since the PNP transistor Q1 is turned on.

Then, the ECU 10 outputs the voltage of the collector electrode of the PNP transistor Q1 (in other words, the charge voltage of the capacitor C1) to the igniter (igniter 30A in this case). The IGBT 32 (described later) of the igniter 30A is driven based on this output signal (hereinafter, control signal) of the ECU 10. Specifically, the voltage for driving the IGBT 32 is generated in the capacitor C1. Moreover, this control signal is a signal that also serves as a power supply voltage of an internal circuit (such as control circuit 34 described later) of the igniter 30A.

### Ignition Device 20

The ignition device 20 is a device for igniting the air-fuel mixture in the combustion chamber of the internal combustion engine. The ignition device 20 includes an ignition coil 22, a DC power supply 23, and an ignition plug 24.

The ignition coil 22 includes a primary coil L1 and a secondary coil L2 with a larger number of turns than the primary coil L1. The ignition coil 22 is also referred to as spark coil, and corresponds to an “inductive load”. The turns ratio is not limited to this.

One end of each of the primary coil L1 and the secondary coil L2 are connected to a positive electrode terminal of the DC power supply 23. A negative electrode terminal of the DC power supply 23 is grounded.

The other end of the primary coil L1 is connected to a C terminal (described later) of the igniter 30A.

The other end of the secondary coil L2 is connected to one electrode of the ignition plug 24. Note that the other electrode of the ignition plug 24 is grounded.

An electromotive force (mutually-induced electromotive force) is generated in the secondary coil L2 of the ignition coil 22 depending on an electromotive force generated in the primary coil L1. Then, the secondary coil L2 supplies the generated electromotive force to the ignition plug 24, and causes the ignition plug 24 to be discharged.

The DC power supply 23 is, for example, a battery for a vehicle, and supplies a voltage (for example, 12 V) to the one ends of the primary coil L1 and the secondary coil L2 of the ignition coil 22.

The ignition plug 24 electrically generates a spark by discharge. For example, a voltage of about 10 kV or higher is applied to the ignition plug 24, and the ignition plug 24 is thereby discharged.

### Igniter 30A

The igniter 30A is a driver circuit configured to drive the ignition coil 22 based on an instruction from the ECU 10. As illustrated in FIG. 1, the igniter 30A includes the IGBT 32, the control circuit 34, resistors R1 to R3, an NMOS transistor M1, a diode D1, a Zener diode ZD1, and a line LN. Moreover, the igniter 30A includes three terminals (gate (G) terminal, collector (C) terminal, and emitter (E) terminal) corresponding to three electrodes (described later) of the IGBT 32, respectively. The igniter 30A is configured with a semiconductor integrated circuit, and is a so-called one-chip igniter in which the IGBT 32, an element configured to control the IGBT 32, and the like are formed on the same substrate (that is, on the same chip).

The IGBT 32 is an element for driving the ignition coil 22, and includes a gate electrode, a collector electrode, and an emitter electrode. The collector electrode is connected to the ignition coil 22 (specifically, primary coil L1) via the C terminal. The emitter electrode is grounded via the E terminal. The IGBT 32 corresponds to a “transistor”. Moreover, the gate electrode of the IGBT 32 corresponds to a “control electrode”, the collector electrode corresponds to a “power supply side electrode”, and the emitter electrode corresponds to a “ground side electrode”. Although the IGBT is used as the transistor in this example, the present disclosure is not limited to this, and for example, a MOSFET may be used. In the case of MOSFET, a drain electrode corresponds to the power supply side electrode, and a source electrode corresponds to the ground side electrode.

The resistor R1 is a resistor with high resistance (for example, 10 kΩ) which makes a slope less steep of a voltage applied to the gate electrode of the IGBT 32 to prevent overshooting caused by abrupt rising of a collector terminal voltage. One end of the resistor R1 is connected to the gate electrode of the IGBT 32, and the other end is connected to the line LN. The resistor R1 corresponds to a “first resistor”.

The diode D1 is a speed-up diode for speeding up turn-off of the IGBT 32. An anode of the diode D1 is connected to the gate electrode of the IGBT 32, and a cathode is connected to the line LN. Specifically, the diode D1 includes the anode connected to the gate electrode of the IGBT 32 and the cathode connected to the line LN, and is connected in parallel with the resistor R1. The diode D1 corresponds to a “third diode”.

The resistor R2 is a resistor for pull-down with high resistance value (1 kΩ or more: for example, 3 kΩ), and is connected between the line LN and the E terminal (ground). The resistor R2 corresponds to “second resistor”.

The Zener diode ZD1 is an element configured to protect the control circuit 34, the NMOS transistor M1, and the like by clamping a voltage to be supplied thereto to a predetermined voltage (for example, 7 V) when an unintentional high voltage is applied from the ECU 10. Moreover, the Zener diode ZD1 is an element configured to absorb a high-frequency noise superimposed on the control signal from the ECU 10 by using a parasitic capacitance included in the diode and prevent unintentional on and off of the IGBT 32. A cathode of the Zener diode ZD1 is connected to the line LN, and an anode is connected to the E terminal. Specifically, the Zener diode ZD1 includes the cathode connected to the line LN and the anode connected to the E terminal, and is connected in parallel with the resistor R2. The Zener diode ZD1 corresponds to a “first diode”.

A source electrode of the NMOS transistor M1 is connected to the gate electrode of the IGBT 32, and a drain electrode is connected (grounded) to the E terminal. Moreover, an output of the control circuit 34 described later is applied to a gate electrode of the NMOS transistor M1.

The control circuit 34 is a circuit configured to control the NMOS transistor M1 and perform overcurrent protection and overheat protection of the IGBT 32, and operates by being supplied with a voltage of the line LN as a power supply. The resistor R3 for current detection is connected between a current sensing terminal of the IGBT 32 and the E terminal, and a voltage of a coupling node between the current sensing terminal of the IGBT 32 and the resistor R3 is inputted into the control circuit 34. Moreover, the control circuit 34 controls the NMOS transistor M1 to be on when the IGBT 32 goes into an overcurrent state. This sets the gate electrode of the IGBT 32 to a ground level, and the IGBT 32 is thus turned off. Moreover, the igniter 30A includes a not-illustrated temperature sensor, and the control circuit 34 controls the NMOS transistor M1 to be on when the temperature reaches or exceeds predetermined temperature. The IGBT 32 is thereby turned off. Accordingly, the IGBT 32 can be protected from overcurrent and overheat.

### Regarding Operation of Ignition System 1A

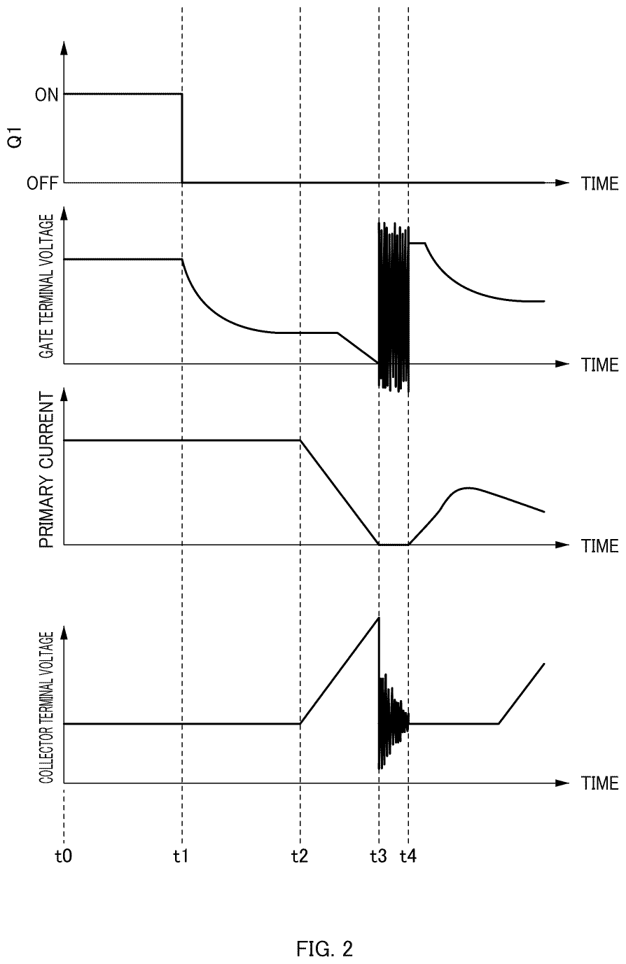

FIG. 2 is a diagram for explaining an operation in ignition of the ignition system 1A. In FIG. 2, a gate terminal voltage illustrates a voltage of the G terminal, a primary current illustrates a current flowing in the primary coil L1 of the ignition coil 22, and a collector terminal voltage illustrates a voltage of the C terminal.

The operation in the ignition of the ignition system 1A is explained below with reference to FIGS. 1 and 2.

At time t0, the microcomputer 12 of the ECU 10 outputs the low signal to the base electrode of the PNP transistor Q1, and the PNP transistor Q1 is turned on.

The G terminal of the igniter 30A goes high (high control signal is inputted into the igniter 30A), since the PNP transistor Q1 is turned on. Moreover, the capacitor C1 is charged since the PNP transistor Q1 is turned on.

The control signal inputted into the igniter 30A is applied to the gate electrode of the IGBT 32 via the line LN and the resistor R1. Thus, a gate voltage of the IGBT 32 exceeds a threshold and the IGBT 32 is turned on, and the primary current flows in the primary coil L1. Specifically, the current flows through a route in order of the DC power supply 23, the primary coil L1, the C terminal, the IGBT 32, the E terminal, and the ground, and energy is stored in the ignition coil 22. Moreover, with the line LN, the power supply voltage is supplied to the control circuit 34 of the igniter 30A, and the control circuit 34 operates (monitor the voltage of the coupling node between the IGBT 32 and the resistor R3).

At time t1, the microcomputer 12 of the ECU 10 outputs the high signal to the base electrode of the PNP transistor Q1, and turns off the PNP transistor Q1. When the PNP transistor Q1 is turned off, the voltage of the G terminal (in other words, voltage of the line LN) does not immediately fall to zero, but gradually decreases since an electric charge is stored in the capacitor C1 and a gate capacitance is in the IGBT 32. The electric charge stored in the capacitor C1 is discharged through a route in order of the G terminal, the resistor R2, the E terminal, and the ground (a route illustrated by the broken line arrow in FIG. 1). The gate capacitance of the IGBT 32 flows through a route in order of the diode D1, the resistor R2, the E terminal, and the ground.

Then, immediately before time t2, the gate voltage of the IGBT 32 falls below the threshold (for example, 2 V), and the IGBT 32 is turned off. This shuts off the primary current flowing in the primary coil L1, and the primary current starts to decrease rapidly. Moreover, the voltage at both ends of the primary coil L1 increases, following the decrease of the primary current of the primary coil L1 (see C terminal voltage in FIG. 2). In this case, a secondary voltage corresponding to the coil turns ratio is generated at both ends of the secondary coil L2.

Then, at time t3, the secondary voltage reaches a predetermined value (for example, several tens of kV), and the ignition plug 24 is discharged. During this discharge of the ignition plug 24, a high voltage generated on the secondary side abruptly changes.

In this case, depending on a parasitic component such as a parasitic inductance of an emitter wiring or a parasitic capacitance between wiring and the like, a voltage of the E terminal may oscillate on the order of MHz as illustrated in FIG. 1. Moreover, the voltages of the G terminal and the C terminal also oscillate, following the oscillation of the voltage of the E terminal as illustrated in FIG. 2.

In a period of voltage of the E terminal>voltage of the G terminal, as illustrated by the solid line arrow in FIG. 1, a current flows through a route in order of the E terminal, the Zener diode ZD1, the G terminal, the capacitor C1, and the ground. Specifically, since the capacitor C1 is charged, the voltage of the G terminal increases. Coupling the resistor R1 with high resistance (for example, 10 kΩ) to the gate electrode of the IGBT 32 can suppress a flow of the current to the gate electrode of the IGBT 32 via the Zener diode ZD1 in this period.

In contrast, in a period of voltage of E terminal<voltage of G terminal, as illustrated by the broken line arrow in FIG. 1, the current flows through a route in order of the capacitor C1, the G terminal, the resistor R2, the E terminal, and the ground, and the electric charge in the capacitor C1 is discharged. In this case, since the resistor R2 has a high resistance (for example, 3 kΩ), time taken for the discharge is longer than charging time. Accordingly, with repeating the oscillation, the voltage of the G terminal gradually increases.

The voltage of the G terminal thereby becomes high at time t4 at which the oscillation settles, and the IGBT 32 that is supposed to be off is turned on, and the primary current flows in the primary coil L1. As described above, an erroneous operation in which the IGBT 32 turns on may occur after the discharging of the ignition plug 24.

Accordingly, in the present embodiment, the erroneous operation is prevented even when the voltage of the E terminal oscillates during the discharge of the ignition plug 24.

### Present Embodiment

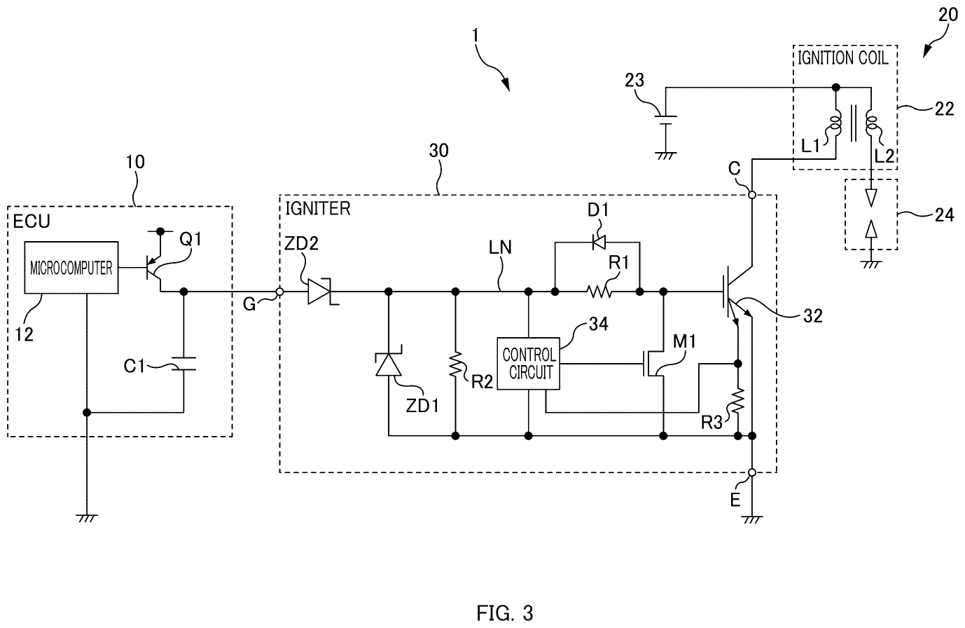

FIG. 3 is a block diagram illustrating a configuration of an ignition system 1 using a driver circuit 30 of the present embodiment. The driver circuit 30 is also referred to as igniter 30.

Like the ignition system 1A of the reference example, the ignition system 1 is a system for an internal combustion engine mounted on an automobile or the like, and includes the ECU 10, the ignition device 20, and the igniter 30.

### Configuration of Igniter 30

The igniter 30 is different from the igniter 30A of the reference example (FIG. 1) in that the igniter 30 includes a Zener diode ZD2. The igniter 30 is configured with a semiconductor integrated circuit like the igniter 30A.

A cathode of the Zener diode ZD2 is connected to the line LN and the cathode of the Zener diode ZD1, and an anode is connected to the G terminal. Specifically, the Zener diode ZD2 includes the cathode connected to the line LN and the anode connected to the capacitor C1 in which the voltage for driving the IGBT 32 is generated. The Zener diode ZD2 corresponds to a “second diode”.

The Zener diode ZD2 is a diode of the same type as the Zener diode ZD1 (Zener diode), and is manufactured in the same manufacturing process of a semiconductor as the Zener diode ZD1. Accordingly, an increase in the man hour and cost for manufacturing the Zener diode ZD2 can be suppressed.

Moreover, a forward voltage of the Zener diode ZD2 is, for example, 0.3 V, and is preferably lower than a forward voltage (0.7 V) of a general diode. This can suppress a decrease in the voltage applied to the gate electrode of the IGBT 32.

Furthermore, providing the Zener diode ZD2 can prevent the erroneous operation in which the IGBT 32 turns on at an unintentional timing after the discharge of the ignition plug 24 as described later.

### Regarding Operation of Ignition System 1

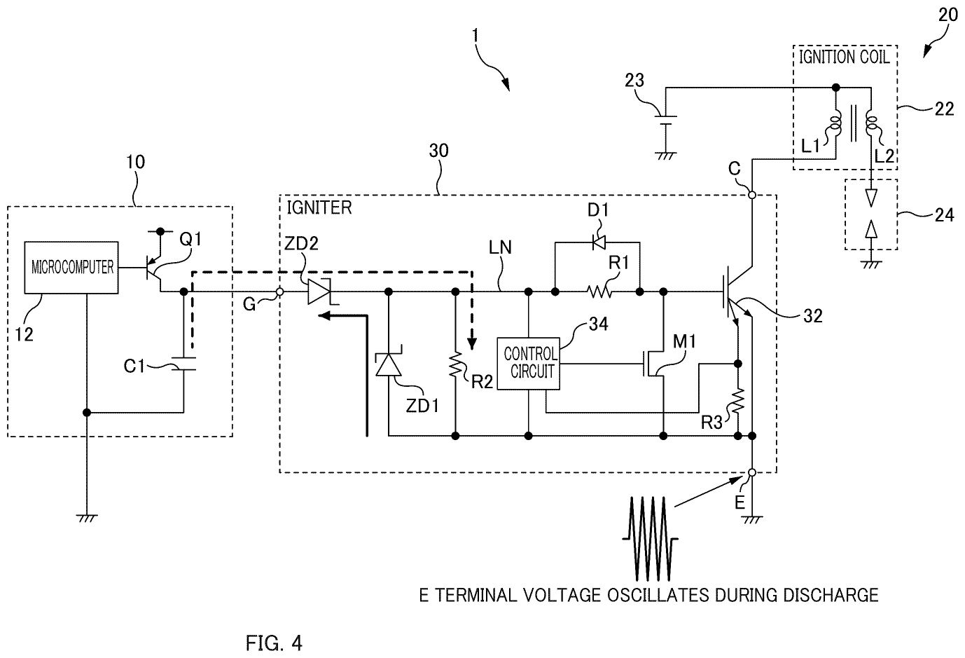

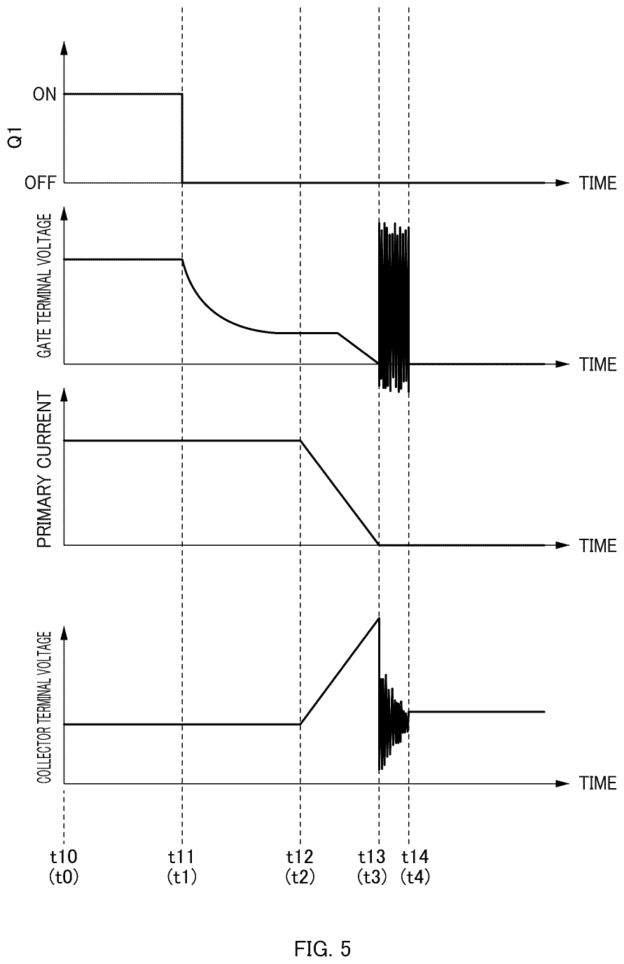

FIG. 4 is an explanatory diagram illustrating a state of a current flowing in the driver circuit (igniter) 30 in the case where the IGBT 32 is turned off. Moreover, FIG. 5 is a diagram for explaining an operation in the ignition of the ignition system 1. Time t10 to 14 in FIG. 5 correspond to time t0 to t4 in FIG. 2, respectively.

The operation of the ignition system 1 in the present embodiment is explained below with reference to FIGS. 4 and 5. Since the operation to time t3 is the same as that in FIG. 2 of the reference example, explanation thereof is omitted. In the present embodiment, providing the Zener diode ZD2 reduces the voltage of the gate electrode of the IGBT 32 from that in the reference example by an amount corresponding to the forward voltage of the Zener diode ZD2. Accordingly, in actual, a slight lag occurs after the time at which the IGBT 32 is turned off (time t12), but this lag is ignored.

In the present embodiment, the voltage of the E terminal also oscillates as in FIG. 4 during the discharge of the ignition plug 24 (time t13).

In the period of voltage of E terminal<voltage of G terminal, as illustrated by the broken line arrow in FIG. 4, the current flows through a route in order of the capacitor C1, the G terminal, the Zener diode ZD2, the resistor R2, the E terminal, and the ground. Specifically, the electric charge in the capacitor C1 is discharged.

Meanwhile, in the period of voltage of E terminal>voltage of G terminal, as illustrated by the solid line arrow in FIG. 4, the current is stopped at the Zener diode ZD2. Thus, the capacitor C1 is not charged.

Accordingly, even when the voltage of the E terminal oscillates, the capacitor C1 is not charged, but is only discharged. Hence, as illustrated in FIG. 5, the voltage of the G terminal at time t4 at which the oscillation settles is substantially zero (the IGBT 32 is not turned on). Moreover, since the IGBT 32 is not turned on, no primary current flows in the primary coil L1.

As described above, in the igniter 30 of the present embodiment, the Zener diode ZD2 is provided, and this can prevent turning-on (erroneous operation) of the IGBT 32 at an unintentional timing.

### Summary

The driver circuit (igniter) 30 of the present embodiment has been explained above. The igniter 30 includes the IGBT 32, the resistors R1 and R2, the Zener diodes ZD1 and ZD2, and the line LN. The collector electrode of the IGBT 32 is connected to the primary coil L1 of the ignition coil 22. The gate electrode of the IGBT 32 is connected to the resistor R1, and the resistor R1 is connected to the line LN. The resistor R2 is connected between the line LN and the ground, and the Zener diode ZD1 includes the cathode connected to the line LN and the anode, and is connected in parallel with the resistor R2. The Zener diode ZD2 includes the cathode connected to the line LN and the anode, and the capacitor C1 in which the voltage for driving the IGBT 32 is generated is connected to the anode. The capacitor C1 is thereby not charged through the route via the Zener diode ZD1 in the case where the voltage of the emitter electrode of the IGBT 32 oscillates. Accordingly, it is possible to prevent the erroneous operation in which the IGBT 32 is turned on at an unintentional timing.

Moreover, the forward voltage of the Zener diode ZD2 is preferably lower than a forward voltage (0.7 V) of a general diode. This can suppress a decrease of the gate electrode in cases such as the case where the IGBT 32 is turned on.

Furthermore, the igniter 30 is configured with the semiconductor integrated circuit, and the Zener diode ZD1 and the Zener diode ZD2 are manufactured in the same manufacturing process of a semiconductor (diodes of the same type). The Zener diode ZD2 can be thereby provided without an increase in the man hour and cost.

Moreover, the elements (IGBT 32, resistors R1 and R2, Zener diodes ZD1 and ZD2, and line LN) which configure the igniter 30 are formed in the semiconductor integrated circuit. The igniter 30 can be thereby formed on the same substrate (for example, silicon substrate) (one-chip igniter can be achieved).

Furthermore, the igniter 30 includes the diode D1 that includes the anode connected to the gate electrode of the IGBT 32 and the cathode connected to the line LN and that is connected in parallel with the resistor R1, and the resistance value of the resistor R1 is larger than the resistance value of the resistor R2. The higher resistance value of the resistor R1 can suppress the flow of the current to the gate electrode of the IGBT 32 via the Zener diode ZD1, for example, in the case where the voltage of the E terminal oscillates (in the case of voltage of E terminal>voltage of G terminal). Moreover, when the IGBT 32 is turned off, the electric charge can be removed from the gate electrode via the diode D1 and the resistor R2, and quick turn-off can be achieved.

Furthermore, the ignition coil 22 is an ignition coil, and the driver circuit 30 is an igniter for ignition control of an internal combustion engine. An erroneous operation such as ignition at an unintentional timing in the internal combustion engine can be thereby suppressed.

Embodiments and modifications of the present disclosure described are simply to facilitate understanding of the present disclosure and are not in any way to be construed as limiting the present disclosure. The present disclosure may variously be changed or altered without departing from its essential features and encompass equivalents thereof.

Although the igniter 30 of the above-mentioned embodiment is provided with the Zener diode ZD2, diodes of types other than the Zener diode (for example, rectifying diode, Schottky barrier diode, and the like) may be provided. However, in a case where the Zener diode ZD2 is provided, the Zener diode ZD2 can be manufactured in the same manufacturing process of a semiconductor as the Zener diode ZD1 as described above, and the increase in the man hour and cost can be thus suppressed. Moreover, since the Zener diode has a lower forward voltage than the rectifying diode, the decrease in the voltage applied to the gate electrode of the IGBT 32 can be suppressed.

Moreover, although the igniter 30 of the above-mentioned embodiment is configured with the semiconductor integrated circuit, the present disclosure is not limited to this, and all or part of the igniter 30 may not be configured with the semiconductor integrated circuit.

The present disclosure is directed to provision of a driver circuit that can prevent an erroneous operation of a transistor configured to drive a load.

The present disclosure can provide a driver circuit that can prevent an erroneous operation of a transistor configured to drive a load.

What is claimed is:

1. A driver circuit comprising:
a transistor including a ground side electrode, a control electrode, and a power supply side electrode for an inductive load to be connected thereto;
a first resistor connected to the control electrode;
a line connected to the first resistor;
a second resistor provided between the line and a ground;
a first diode, including:
a cathode connected to the line, and
an anode,
the first diode being connected in parallel with the second resistor; and
a second diode including:
a cathode connected to the line, and
an anode for connecting to a capacitor, thereby receiving a voltage generated in the capacitor for driving the transistor.

2. The driver circuit according to claim 1, wherein a forward voltage of the second diode is lower than 0.7 V.

3. The driver circuit according to claim 1, wherein
the driver circuit is configured with a semiconductor integrated circuit, and
the first diode and the second diode are manufactured in a same manufacturing process.

4. The driver circuit according to claim 3, wherein the first diode and the second diode, the first resistor and the second resistor, and the transistor are formed in the semiconductor integrated circuit.

5. The driver circuit according to claim 1, further comprising:
a third diode, including:
an anode connected to the control electrode, and
a cathode connected to the line,
the third diode being connected in parallel with the first resistor, wherein
a resistance value of the first resistor is larger than a resistance value of the second resistor.

6. The driver circuit according to claim 1, wherein
the inductive load is an ignition coil, and
the driver circuit is an igniter for ignition control of an internal combustion engine.
